(19) United States
(12) Patent Application Publication
(10) Pub. No.: US 2007/0158835 A1
(43) Pub. Date: Jul. 12, 2007

(54) Method for designing interconnect for a new processing technology

(75) Inventors: Jian-Hong Lin, Huwei Town (TW); Hsueh-Chung Chen, Yonghe City (TW); Yi-Lung Cheng, Dashuei Town (TW); Ta-Wei Lee, Luodong Town (TW); Chih-Tao Lin, Hsinchu City (TW); Jyh-Kang Ting, Baoshan Township (TW); Lee-Chung Lu, Taipei (TW)

Correspondence Address: Howard Chen, Esq.;Preston Gates & Ellis LLP, Suite 1700, 55 Second Street, San Francisco, CA, 94105, US

(73) Assignee: Taiwan Semiconductor Manufacturing Co., Ltd.

(21) Appl. No.: 11/332,566

(22) Filed: Jan. 12, 2006

(51) Int. Cl. H01L 23/48

(52) U.S. Cl. 257/734

(57) ABSTRACT

A method is disclosed for determining a size of an interconnect between a first and a second conductor respectively in two layers of an integrated circuit while scaling from a reference processing technology to a predetermined processing technology. The method comprises selecting a set of design rules for the conductors based on the predetermined processing technology, determining a length of a first side of a rectangular cross sectional area of the interconnect based on the design rules and a scaling rule for scaling such a length from the reference processing technology to the predetermined processing technology, and determining a length of a second side of the cross sectional area of the interconnect for compensating an increase of a resistance of the interconnect due to the scaling from the reference processing technology to the predetermined processing technology.

### FIELD OF THE INVENTION

This invention generally relates to the design of interconnects on integrated circuits, and more particularly, to an improved method for designing interconnects between two layers with appropriate effective resistance.

### BACKGROUND OF THE INVENTION

Semiconductor technology has developed rapidly in the recent years. The newer manufacturing technologies produce integrated circuits (IC) with smaller feature sizes, making it possible to continuously shrink the size of a die and packing more dies on a wafer. It is well known that different generations of the manufacturing technologies are identified by their respective basic transistor gate width. For example, 0.18 u processing technology has a gate width of 0.18 u, while 90 nm has its gate width down at 90 nanometers. While developing a new processing technology for manufacturing IC products, it is not simply a “shrinking” job. The “shrinking” effect of the newer processing technology will bring various manufacturing challenges, sometimes unexpected or unpredictable.

One challenge in this continuous scale down process of integrated circuits is the design of interconnects (or vias) between two conductive lines on two different layers. For example, metal conductors on the first metal layer M1 and the second metal layer M2 are interconnected by means of a metal interconnect typically formed by filling a via with a suitable metal, such as copper or aluminum. As interconnects are scaled down, the resistivity of the interconnect increases much faster compared to that of a metal conductor wire because of the two dimensional scaling nature of the interconnects.

Referring first to FIGS. 1(a) and 1(b), a pair of metal conductor wires 10, 12 residing in different layers of an integrated circuit have overlapping end portions that are connected by a pair of metal interconnects 14a, 14b which are laterally spaced apart from each other and have a cross section that is rectangular in shape. The sizes of the cross sectional areas of the interconnects 14a, 14b are selected so as to reduce the collective resistance of the interconnection between the conductors 10, 12 to achieve certain design rules of the IC.

The resistance of each of the interconnects 14a , 14b, is given by the formula:

$$R = \frac{ρ \cdot L}{A}$$

where ρ is the resistivity of the interconnect metal, L is the length of the interconnect and A is the cross sectional area of the interconnect. Thus, it can be seen that as feature size decreases, the resistance of the metal interconnect increases quadratically.

Because of the need to laterally space the interconnects 14a, 14b, it is necessary to provide lateral extensions 15 on the ends of the conductors 10 and 12, otherwise the interconnects 14a, 14b would extend beyond the lateral boundaries of the conductors 10, 12. This is referred to as a “dog bone” design. Such a dog bone design is used in order to reduce the resistance of interconnects to within design standards. However, the dog bone design has significant deficiencies. For example, the “holes” are small, and thus making it hard to process. Secondly, it has relative high interconnect resistance. Also, due to the extended contact areas, precious space in the IC layout is consumed. Especially for these generations under 65 nm, the interconnect resistance can abruptly increase. Increasing the number of interconnects is one conventional way to reduce or eliminate the resistance increase for the advanced processing technology, but it will cause negative impacts on reliability performance. For processing technology under 45 nm, interconnects of a cylindrical shape are typically used, but the interconnects of a cylindrical shape are harder to process.

Accordingly, there is a clear need for an improved method for designing interconnects as the processing technology advances.

### SUMMARY OF THE INVENTION

The present disclosure provides a method for determining a size of an interconnect between a first and a second conductor respectively in two layers of an integrated circuit while scaling from a reference processing technology to a predetermined processing technology. The method comprises selecting a set of design rules for the conductors based on the predetermined processing technology, determining a length of a first side of a rectangular cross sectional area of the interconnect based on the design rules and a scaling rule for scaling such a length from the reference processing technology to the predetermined processing technology, and determining a length of a second side of the cross sectional area of the interconnect for compensating an increase of a resistance of the interconnect due to the scaling from the reference processing technology to the predetermined processing technology.

An interconnect determined by such a method does not need the dog bone design of the conventional and still compensate for the resistance increase due to the change of processing technologies.

### BRIEF DESCRIPTION OF THE DRAWINGS

FIG. 1(a) is a side view of multiple interconnects between two conductors according one type of prior art layout;

FIG. 1(b) is a top view of the interconnects shown in FIG. 1(a);

FIG. 2(a) is a side view of an interconnect between two conductors, in accordance with one embodiment of the present invention;

FIG. 2(b) is a top view of the interconnect and conductors shown in the FIG. 2(a);

FIG. 2(c) is another top view of the inventive interconnect to connect conductors in a different layout pattern;

FIG. 3 is a chart showing the relationship between resistivity and line width of a conductive line; and

FIG. 4 is a flow chart showing steps for determining interconnect size using a new processing technology according to one embodiment of the present invention.

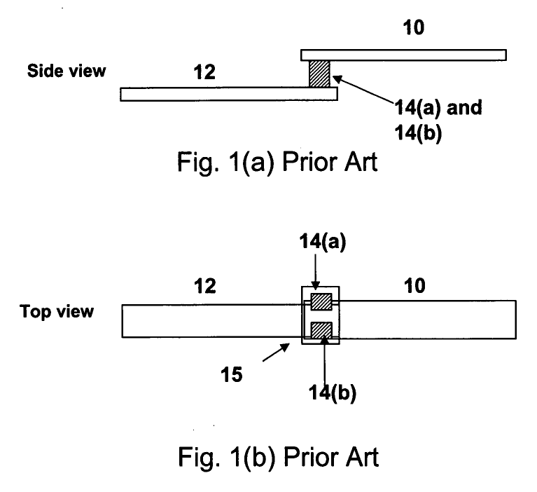

### DETAILED DESCRIPTION

The present disclosure provides a method to determine the size of interconnects for a new processing technology based on a reference processing technology. While determining the size of the interconnects for the new processing technology, the interconnect resistance is considered and compensated inherently.

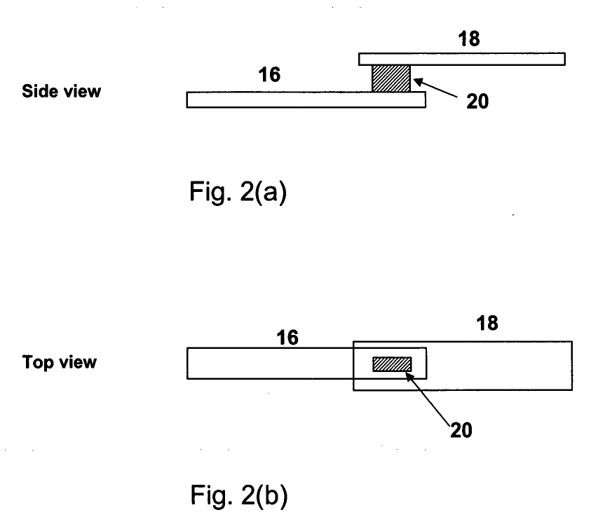

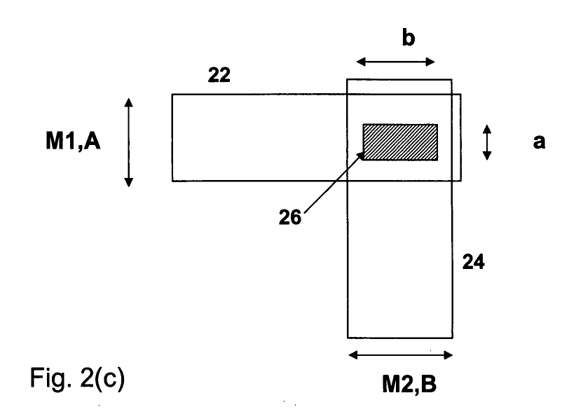

Referring now to FIGS. 2(a)-2(c), according to the present invention, a novel, single interconnect 20 is provided between a pair of metal conductors 16, 18 (or M1 and M2 respectively) lying in respective layers of an integrated circuit. The ends of the conductors 16, 18 have overlapping portions that are electrically connected by the interconnect 20 which extends perpendicular to the plane of the conductor 16, 18. The single interconnect 20 is formed by filling a conductive material such as copper through a small via that is also of rectangular cross section. When determining the width and length of the interconnect, a particular relation is studied according to the present invention so that the interconnect is sized to compensate the increase of the resistance while shrinking the feature size to a smaller one.

It is understood that the interconnect may also be employed to connect overlapping, transverse oriented connectors as shown in FIG. 2(c). In this particular example, conductors 22, 24 (or M1 and M2 respectively) extend at right angles to each other and include overlapping end portions which are electrically interconnected by an interconnect 26. The cross section of the interconnect 26 is substantially rectangular. The width of the interconnect 26 is proportional to the width “A” of the conductor 22 while its length is proportional to the width “B” of conductor 24 under the design rules. As such, the ratio B/A is the same as the ratio between the length “b′” and width “a” of the interconnect 26. It is understood that the effective resistivity can be indicated by multiplying “a” with “b”, i.e., “a×b”, which is desired to be substantially similar to an equivalent interconnect made by a previous processing technology generation.

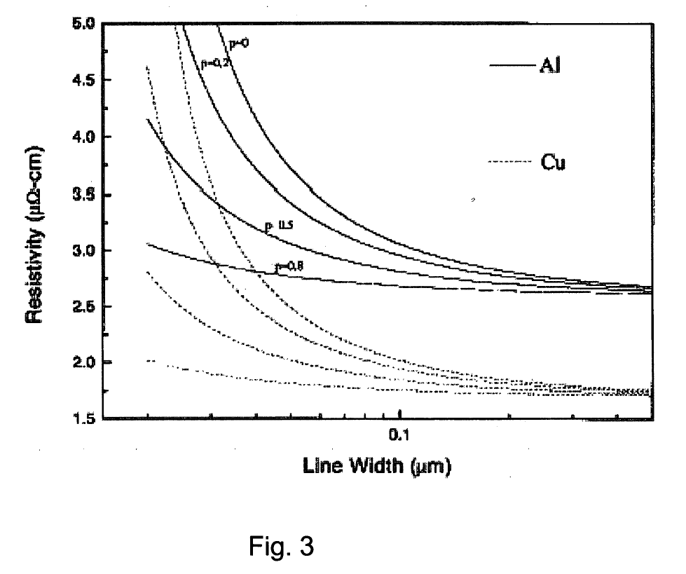

FIG. 3 is a chart showing the relation between resistivity and line width of a conductive line in the IC (see, F. Chen and D. Gardner, “Influence of line dimensions on the resistance of Cu interconnects”, IEEE Electron Device Letters, Vol. 19, NO. 12, p.p. 208-510, December 1998). The top four curves are for aluminum lines and the bottom four curves are for copper lines, both of which are popular conducting materials used for making conductive lines in IC. Each curve represents the resistivity change with reference to the change of line width, and each represents a different fraction of the electrons that are elastically scattered. For example, the fraction is represented by “p” in the chart with the top most curve representing no scattering of electrons, while the bottom most of the four curves for the aluminum group representing 80% of the electrons are elastically scattered. It can be seen that as the line width is getting smaller, the interconnect resistance increases nonlinearly, and the interconnect resistance can outgrow that of the regular conductive lines. It is understood that in 0.13 um processing technology, the interconnect via resistance is about 0.7Ω, and at 90 nm generation, it is about 1.5Ω, and at 65 nm generation, the interconnect resistance has grown to about 3Ω.

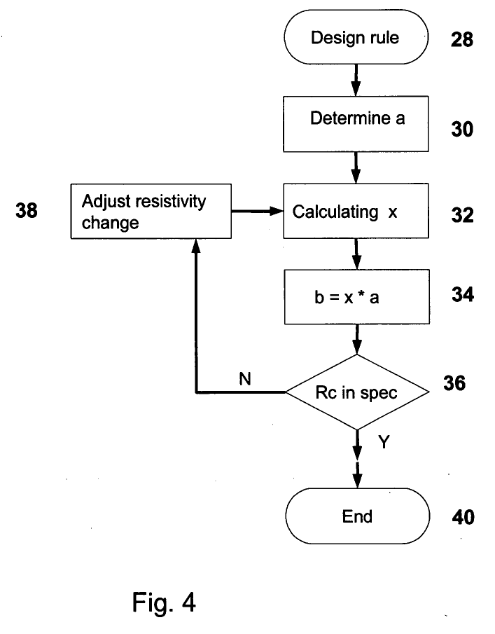

FIG. 4 depicts a flow diagram showing steps taken to determine the size of the interconnect using a predetermined processing technology. The method starts at step 28 with the selection of a set of designed standards or rules based on the desired or the new processing technology. As previously mentioned, the design rules dictate feature sizes and performance parameters for the new IC processing technology. Next at step 30, the width dimension “a” of the interconnect is determined, which is proportional to the width of the first conductive line, e.g., M1, based on a scaling rule. The scaling rule represents the changes of various element dimensions from a reference processing technology to a desired processing technology. For example, if the 90 nm processing technology is the reference processing technology, and the 65 nm processing technology is the desired processing technology, the interconnect width “a” is scaled down from a standard 120 nm to 90 nm. Next, an appropriate coefficient “x” needs to be determined based on resistivity change as shown in FIG. 3 in step 32. For example, when the technology is migrating from 90 nm generation to 65 nm generation, with known value representing the fraction of scattered electrons, a particular curve can be used to check the change of resistivity, or the ratio between two different resistivity values corresponding to two different line widths. This can also be examined by experimental data. Once this coefficient “x” is determined, the length “b” for the interconnect, which is proportional to the width of a second conductive line M2 that intersects with M1 can be calculated by simply multiplying “x” with “a” at step 34. The determination of the “b” intends to compensate the increase of the interconnect resistance due to the scaling from the reference processing technology to the desired processing technology. The interconnect resistance R_{c} is then obtained based on “a” and “b” in step 36, and checked to see whether this value is about the same as its counterpart made by a previous processing technology. It is understood that certain rules can be set for determining whether this interconnect resistance is acceptable. For example, if the interconnect resistance is below a predetermined threshold specified, then it is acceptable. On the other hand, if it is not, the coefficient “x” is redetermined based on the adjustment of the resistivity change through experiments or from the ratio ρ*/ρ₀ where ρ* is the measured resistivity coefficient for the current technology and ρ₀ is the bulk resistivity used as a reference at step 38. An adjustment is then made in the value of “x” at step 32. It is noted that the measured resistivity coefficient ρ* is an empirical parameter, which can be obtained at the beginning of a new technology. As a result, in some cases, one may need to re-check the “b,” as well as “x,” while in other cases where ρ* is determined precisely in advance, there is no need to re-check “x.” Once the interconnect resistance is within a specified range at 36, the design process is complete and ends at step 40. The above description used the actual width and length of the interconnect for illustration. It can be appreciated that since a:b≈A:B, the calculation of the actual width and length of the interconnect can be done by appropriately determining the two line widths of M1 and M2, i.e., A and B as long as the ratio a:A and b:B is predetermined by the design rules of the current processing technology. In other words, if one line width is determined for the current processing technology, and in order to maintain similar interconnect resistance, the width of an intersecting line can be appropriately determined.

Table 1 shows relative dimensions of the line widths A and B for two conductors M1, M2 in various processing technologies in order to maintain similar interconnect resistance. It can be seen that from 0.13 um processing technology to 65 nm processing technology, the coefficient “x”, which is the ratio between the width of conductor M2 to the width of conductor M1 is slightly different in order not to see any abrupt increase of interconnect resistance.

TABLE 1

| | Processing Technology | | |
|---|---|---|---|
| | (nm) | | |
| | 130 | 90 | 65 |
| M1 width | 160 | 120 | 90 |
| M2 width | 200 | 140 | 110 |
| x | 1.25 | 1.17 | 1.22 |

In accordance with the present invention, recognition is made of the fact that a single, rectangular interconnect can be employed to meet particular design rules and application requirements by controlling the ratio between the widths of intersecting conductors and the cross sectional area of the interconnect. The use of an enlarged single interconnect with a cross section of a rectangular shape is capable of compensating for the increase in the interconnect resistance. In contrast to the prior art use of multiple, square interconnects, the single, rectangular interconnect of the present invention not only provides superior space utilization on the IC, but facilitates layout flexibility, improves space utilization and, significantly, allows direct scaling of existing designs without the need to reconfigure the layout for the interconnects.

From the foregoing, it is apparent that the novel method to determining the size of interconnects produced thereby not only provide for the reliable accomplishment of the objects of the invention but do so in a particularly simple and economical manner. Those skilled in the art will recognize that various modifications may be made to the embodiment chosen to illustrate the invention without departing from the spirit and scope of the present contribution of the art. Accordingly, it is to be understood that the protection sought and to be afforded hereby should be deemed to extend to the subject matter claimed in all equivalents thereof fairly within the scope of the invention.

What is claimed is:

1. An interconnect of an integrated circuit produced by a predetermined processing technology, comprising:
a first conductor on a first layer of the integrated circuit;
a second conductor on a second layer of the integrated circuit, a portion of the first conductor underlying a portion of the second conductor; and,
only one electrically conductive interconnect extending between and connecting the overlying portions of the first and second conductors,
wherein the interconnect has a substantially rectangular cross sectional area parallel to the first and second layer with its first side having a predetermined length set according to a scaling rule with regard to a reference processing technology, and a second side having a predetermined length set for compensating an increase of resistance of the interconnect due to a scaling from the reference processing technology to the predetermined processing technology.

2. The interconnect of claim 1, wherein a ratio between the first and second sides of the cross sectional area of the interconnect is determined based on a resistivity change of the electrically conductive interconnect.

3. The interconnect of claim 1, wherein the predetermined processing technology is below 65 nm generation.

4. The interconnect of claim 1, wherein the reference processing technology is at least of 65 nm generation.

5. The interconnect of claim 1, wherein the interconnect is made of Cu or Al.

6. A method for determining a size of an interconnect between a first and a second conductor respectively in two layers of an integrated circuit while scaling from a reference processing technology to a predetermined processing technology, the method comprising:
selecting a set of design rules for the conductors based on the predetermined processing technology;
determining a length of a first side of a rectangular cross sectional area of the interconnect based on the design rules and a scaling rule for scaling such a length from the reference processing technology to the predetermined processing technology; and
determining a length of a second side of the cross sectional area of the interconnect for compensating an increase of a resistance of the interconnect due to the scaling from the reference processing technology to the predetermined processing technology.

7. The method of claim 6, wherein determining a length of a second side further includes determining a ratio representing a resistivity change of the interconnect due to the scaling from the reference processing technology to the predetermined processing technology.

8. The method of claim 7 wherein determining the ratio further includes determining a measured resistivity coefficient for the predetermined processing technology and a bulk resistivity for the reference processing technology.

9. The method of claim 8 further comprising adjusting the ratio representing a resistivity change of the interconnect due to the scaling from the reference processing technology to the predetermined processing technology if the resistance is not acceptable according to a predetermined rule.

10. The method of claim 6 wherein the reference processing technology is at least of 65 nm generation.

11. The method of claim 6 wherein the predetermined processing technology is at least of 45 nm generation.

12. The method of claim 6 wherein the interconnect is made of Cu or Al.

13. A method for determining a size of an interconnect between a first and a second conductor respectively in two layers of an integrated circuit while scaling from a reference processing technology to a predetermined processing technology, the method comprising:
selecting a set of design rules for the conductors based on the predetermined processing technology;
determining a width of the first conductor based on the design rules and a scaling rule for scaling such a length from the reference processing technology to the predetermined processing technology, the first conductor being proportional to a length of a first side of a rectangular cross sectional area of the interconnect; and determining a width of the second conductor proportional to a length of a second side of the cross sectional area of the interconnect for compensating an increase of a resistance of the interconnect due to the scaling from the reference processing technology to the predetermined processing technology.

14. The method of claim 13, wherein determining a width of the second conductor further includes determining a ratio representing a resistivity change of the interconnect due to the scaling from the reference processing technology to the predetermined processing technology.

15. The method of claim 14 wherein determining the ratio further includes determining a measured resistivity coefficient for the predetermined processing technology and a bulk resistivity for the reference processing technology.

16. The method of claim 15 further comprising adjusting the ratio representing a resistivity change of the interconnect due to the scaling from the reference processing technology to the predetermined processing technology if the resistance is not acceptable according to a predetermined rule.

17. The method of claim 13 wherein the reference processing technology is at least of 65 nm generation.

18. The method of claim 13 wherein the predetermined processing technology is at least of 45 nm generation.

19. The method of claim 13 wherein the interconnect is made of Cu or Al.
